(19) United States
(12) Patent Application Publication
(10) Pub. No.: US 2025/0331407 A1
(43) Pub. Date: Oct. 23, 2025

(54) DISPLAY DEVICE AND OPTICAL DEVICE

(71) Applicant: Samsung Display Co., LTD., Yongin-si (KR)

(72) Inventors: Mi Hwa LEE, Yongin-si (KR); Oh Jeong KWON, Yongin-si (KR); Dae Won KIM, Yongin-si (KR); Tae Ho KIM, Yongin-si (KR); Jong Ho SON, Yongin-si (KR); Sung Gyu JANG, Yongin-si (KR)

(21) Appl. No.: 19/013,263

(22) Filed: Jan. 8, 2025

(30) Foreign Application Priority Data
Apr. 18, 2024 (KR) 10-2024-0052038

(51) Int. Cl. H10K 59/80; G02B 5/30; H10K 59/131; H10K 59/38; H10K 102/00

(52) U.S. Cl. CPC H10K 59/8793; G02B 5/3058; H10K 59/131; H10K 59/38; H10K 59/874; H10K 2102/351

(57) ABSTRACT

A display device and an optical device are provided. The display device includes a substrate, a display element layer disposed on the substrate, and including a first electrode, a light emitting layer, and a second electrode, a phase retardation layer disposed on the display element layer, a barrier layer disposed on a side surface of the phase retardation layer, and a wire grid polarizer disposed on the phase retardation layer, wherein the barrier layer contains a moisture absorbent material.

This application claims priority to Korean Patent Application No. 10-2024-0052038, filed on Apr. 18, 2024, and all the benefits accruing therefrom under 35 U.S.C. § 119, the content of which in its entirety is herein incorporated by reference.

### BACKGROUND

### 1. Technical Field

The present disclosure relates to a display device and an optical device including the same.

### 2. Description of the Related Art

A head mounted display (“HMD”) is an image display device that is worn on a user's head in the form of glasses or helmets to form a focus at a close distance in front of the user's eyes. The head mounted display may implement virtual reality (“VR”) or augmented reality (“AR”).

The head mounted display magnifies an image displayed on a small display device by using a plurality of lenses, and displays the magnified image. Therefore, the display device applied to the head mounted display is desirable to provide high-resolution images, for example, images with a resolution of 3000 Pixels Per Inch (“PPI”) or higher. To this end, an organic light emitting diode on silicon (“OLEDoS”), which is a high-resolution small organic light emitting display device, is used as the display device applied to the head mounted display. The OLEDoS is an image display device in which an organic light emitting diode (OLED) is disposed on a semiconductor wafer substrate on which a complementary metal oxide semiconductor (“CMOS”) is disposed.

### SUMMARY

Aspects of the present disclosure provide a display device and an optical device capable of improving reliability by preventing moisture permeation.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate; a display element layer disposed on the substrate, and including a first electrode, a light emitting layer, and a second electrode; a phase retardation layer disposed on the display element layer; a barrier layer disposed on a side surface of the phase retardation layer; and a wire grid polarizer disposed on the phase retardation layer, where the barrier layer contains a moisture absorbent material.

In an embodiment, the barrier layer may be in contact with the side surface of the phase retardation layer, and extend to a top surface of the substrate.

In an embodiment, the barrier layer may be disposed to extend further between the phase retardation layer and the wire grid polarizer, and the barrier layer may cover the phase retardation layer.

In an embodiment, the barrier layer may be in contact with a top surface of the phase retardation layer and a bottom surface of the wire grid polarizer.

In an embodiment, the display device may further include an encapsulation layer disposed on the display element layer, and covering the display element layer, and a color filter layer disposed on the encapsulation layer, where the phase retardation layer may be disposed on the color filter layer.

In an embodiment, the barrier layer may be in contact with the side surface of the phase retardation layer, a side surface of the color filter layer, and a side surface of the encapsulation layer.

In an embodiment, the barrier layer may be disposed to extend further between the phase retardation layer and the wire grid polarizer, and the barrier layer may cover the phase retardation layer and may extend to a top surface of the encapsulation layer.

In an embodiment, the barrier layer may contain a base resin, and the moisture absorbent material may be dispersed in the base resin.

In an embodiment, the moisture absorbent material may be contained in an amount of 1 weight percentage (wt %) to 50 wt % with respect to all materials in the barrier layer.

In an embodiment, the moisture absorbent material may contain at least one of metal salt or metal oxide.

In an embodiment, a thickness of the barrier layer may be 0.1 micrometers (μm) to 5 μm.

According to an aspect of the present disclosure, a display device includes: a substrate including a display area and a non-display area disposed around the display area; a display element layer disposed on the display area of the substrate, and including a first electrode, a light emitting layer, and a second electrode; a phase retardation layer disposed on the display element layer; a wire grid polarizer disposed on the phase retardation layer; a cover layer disposed on the wire grid polarizer, and facing the substrate; a coupling member coupling the substrate to the cover layer; and a barrier layer disposed in the non-display area of the substrate, and in contact with each of the substrate and the cover layer, where the barrier layer contains a moisture absorbent material.

In an embodiment, the coupling member may be disposed in the non-display area, and the barrier layer may be disposed between the display area and the coupling member in a plan view.

In an embodiment, the barrier layer may be disposed to surround the display area in a plan view, and may be disposed to be spaced apart from the display element layer, the phase retardation layer, and the wire grid polarizer.

In an embodiment, the barrier layer may contain a base resin, and the moisture absorbent material may be dispersed in the base resin.

In an embodiment, the moisture absorbent material may be contained in an amount of 1 wt % to 50 wt % with respect to all materials in the barrier layer.

According to an aspect of the present disclosure, an optical device includes a display device, and an optical path changing member disposed on the display device, where the display device includes: a substrate; a display element layer disposed on the substrate, and including a first electrode, a light emitting layer, and a second electrode; a phase retardation layer disposed on the display element layer; a barrier layer disposed on a side surface of the phase retardation layer; and a wire grid polarizer disposed on the phase retardation layer, where the barrier layer contains a moisture absorbent material.

In an embodiment, the barrier layer may be in contact with the side surface of the phase retardation layer, and extend to a top surface of the substrate.

In an embodiment, the optical device may further include an encapsulation layer disposed on the display element layer, and covering the display element layer, and a color filter layer disposed on the encapsulation layer, where the phase retardation layer is disposed on the color filter layer.

In an embodiment, the moisture absorbent material may be contained in an amount of 1 wt % to 50 wt % with respect to all materials in the barrier layer.

According to an aspect of the present disclosure, an electronic device may comprise a display device configured to provide an image, a processor configured to provide an image data signal to the display device, a memory configured to store a data information for operation, and a power module configured to generate power, wherein the display device comprises a substrate; a display element layer disposed on the substrate, and including a first electrode, a light emitting layer, and a second electrode; a phase retardation layer disposed on the display element layer; a barrier layer disposed on a side surface of the phase retardation layer; and a wire grid polarizer disposed on the phase retardation layer, where the barrier layer contains a moisture absorbent material.

A display device and an optical device according to one embodiment include a barrier layer capable of protecting a phase retardation layer from moisture, thereby effectively preventing a change in phase difference and a change in black luminance of the display device while preventing occurrence of haze as well.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view showing a display device according to one embodiment;

FIG. 2 is a layout diagram illustrating an example of the display panel shown in FIG. 1;

FIG. 3 is an equivalent circuit diagram of a first pixel according to one embodiment;

FIG. 4 is a layout diagram illustrating an example of a display panel according to one embodiment;

FIG. 5 is a layout diagram showing embodiments of the display area of FIG. 4;

FIG. 6 is a cross-sectional view illustrating an example of the display panel taken along line X-X′ of FIG. 5;

FIG. 7 is a cross-sectional view illustrating a cross section of the display panel according to one embodiment;

FIG. 8 is a cross-sectional view schematically showing a barrier layer according to one embodiment;

FIG. 9 is a cross-sectional view showing an example of a display panel according to another embodiment;

FIG. 10 is a cross-sectional view showing an example of a display panel according to still another embodiment;

FIG. 11 is a plan view showing an example of a display panel according to still another embodiment of FIG. 10;

FIG. 12 is a cross-sectional view showing a display panel according to still another embodiment;

FIG. 13 presents an image after a reliability test of a display panel according to a comparative example;

FIG. 14 provides an image after a reliability test of a display panel according to one embodiment;

FIG. 15 is a perspective view illustrating a head mounted display according to one embodiment;

FIG. 16 is an exploded perspective view illustrating an example of the head mounted display of FIG. 15; and

FIG. 17 is a perspective view illustrating a head mounted display according to one embodiment.

FIG. 18 is a block diagram of an electronic device according to one embodiment of the present disclosure.

FIG. 19 is a schematic diagram of an electronic device according to various embodiments of the present disclosure.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments will be described with reference to the accompanying drawings.

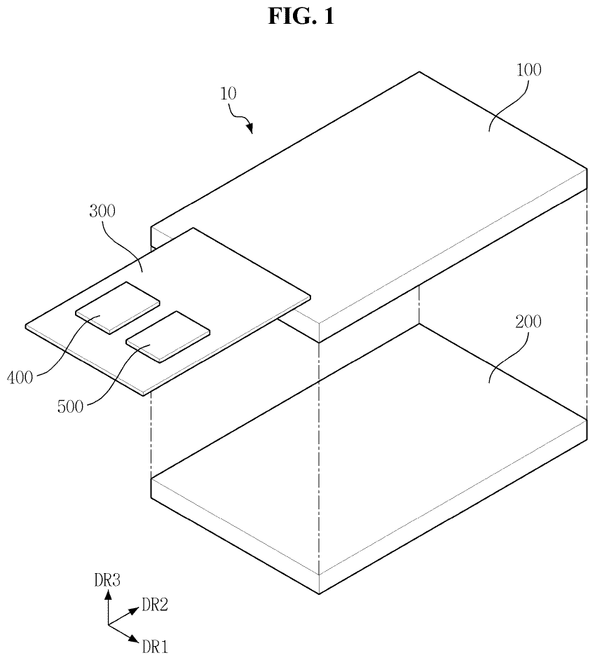

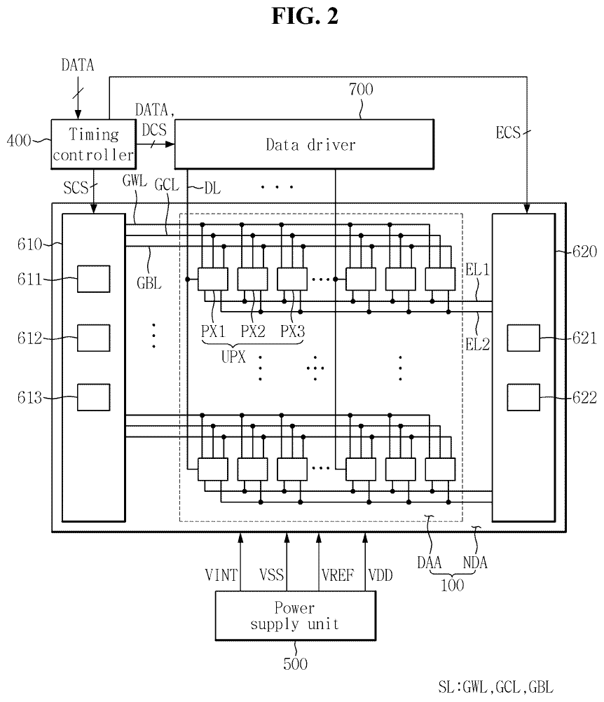

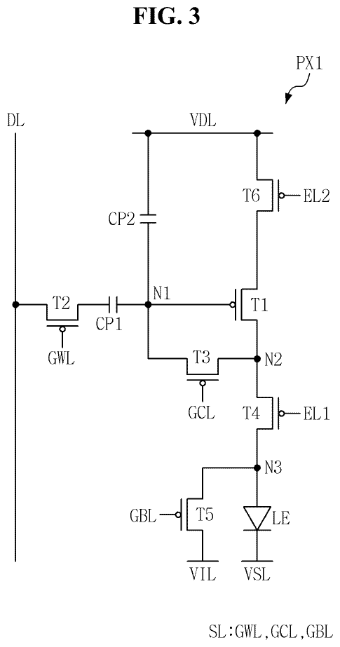

FIG. 1 is an exploded perspective view showing a display device according to one embodiment. FIG. 2 is a layout diagram illustrating an example of the display panel shown in FIG. 1. FIG. 3 is an equivalent circuit diagram of a first pixel according to one embodiment.

Referring to FIGS. 1 and 2, a display device 10 according to one embodiment is a device displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (“PMP”), a navigation system, an ultramobile PC (“UMPC”) or the like. For example, the display device 10 according to one embodiment may be applied as a display unit of a television, a laptop, a monitor, a billboard, or an Internet-of-Things (“IoT”) terminal. Alternatively, the display device 10 according to one embodiment may be applied to a smart watch, a watch phone, a head mounted display (HMD) for implementing virtual reality and augmented reality, and the like.

The display device 10 according to one embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the present specification is not limited thereto.

The display panel 100 may include a display area DAA displaying an image and a non-display area NDA not displaying an image as shown in FIG. 2.

The display area DAA may include a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

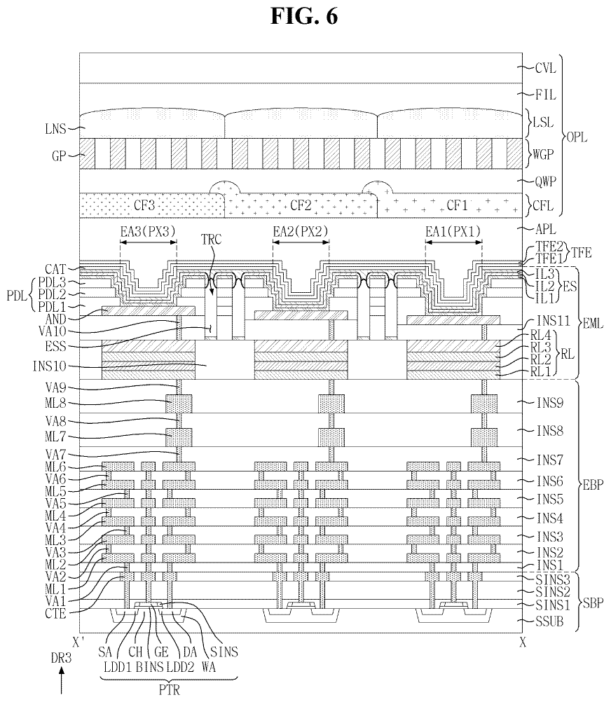

Each of a plurality of unit pixels UPX may include a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be disposed on a semiconductor substrate SSUB (see FIG. 6). For example, the plurality of pixel transistors of a data driver 700 may be formed of complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include a plurality of scan transistors, and the emission driver 620 may include a plurality of light emitting transistors. The plurality of scan transistors and the plurality of light emitting transistors may be formed on the semiconductor substrate SSUB (see FIG. 6) through a semiconductor process. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the embodiment of the present specification is not limited thereto. For another example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive the scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may receive the emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 6) through a semiconductor process. For example, the plurality of data transistors may be formed of CMOS.

The data driver 700 may receive the digital video data DATA and the data timing control signal DCS from the timing control circuit 400. The data driver 700 converts the digital video data DATA into analog data voltages according to the data timing control signal DCS and outputs the analog data voltages to the data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

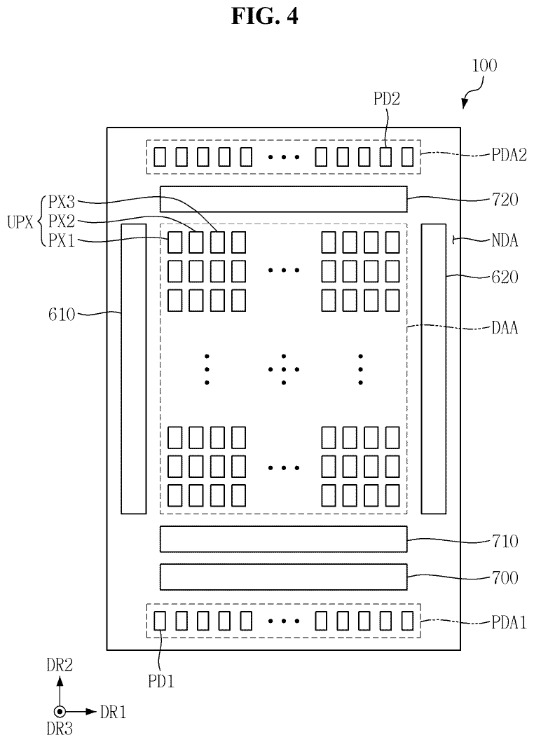

The circuit board 300 may be electrically connected to a plurality of first pads PD1 (see FIG. 4) of a first pad portion PDA (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (“IC”) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 6) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is an equivalent circuit diagram of a first pixel according to one embodiment.

Referring to FIG. 3, a first pixel PX1 may be connected to the write scan line GWL, the control scan line GCL, the bias scan line GBL, the first emission control line EL1, the second emission control line EL2, and the data line DL. In addition, the first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first pixel PX1 may include a plurality of transistors T1 to T6, a light emitting element LE, a first capacitor CP1, and a second capacitor CP2.

The light emitting element LE emits light in response to a driving current Ids flowing through the channel of a first transistor T1. The emission amount of the light emitting element LE may be proportional to the driving current Ids. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the present specification is not limited thereto. For another example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 may include a gate electrode connected to a first node N1, a source electrode connected to the drain electrode of the sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (“MOSFET”). For example, each of the first to sixth transistors T1 to T6 may be a P-type MOSFET, but the embodiment of the present specification is not limited thereto. Each of the first to sixth transistors T1 to T6 may be an N-type MOSFET in another embodiment. Alternatively, some of the first to sixth transistors T1 to T6 may be P-type MOSFETs, and each of the remaining transistors may be an N-type MOSFET.

Although it is illustrated in FIG. 3 that the first pixel PX1 includes the six transistors T1 to T6 and the two capacitors C1 and C2, it should be noted that the equivalent circuit diagram of the first pixel PX1 is not limited to the example shown in FIG. 3. For example, the number of the transistors and the number of the capacitors of the first pixel PX1 are not limited to the example shown in FIG. 3.

In addition, the equivalent circuit diagram of a second pixel PX2 and the equivalent circuit diagram of a third pixel PX3 may be substantially the same as the equivalent circuit diagram of the first pixel PX1 described in conjunction with FIG. 3. Thus, in the present specification, description of the equivalent circuit diagram of the second pixel PX2 and the equivalent circuit diagram of the third pixel PX3 will be omitted.

FIG. 4 is a layout diagram illustrating an example of a display panel according to one embodiment.

Referring to FIG. 4, the display area DAA of the display panel 100 according to one embodiment may include the plurality of pixels PX arranged in a matrix form. The non-display area NDA of the display panel 100 according to one embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the embodiment of the present specification is not limited thereto, and the scan driver 610 and the emission driver 620 may be disposed on both the first side and the second side of the display area DAA in another embodiment. The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

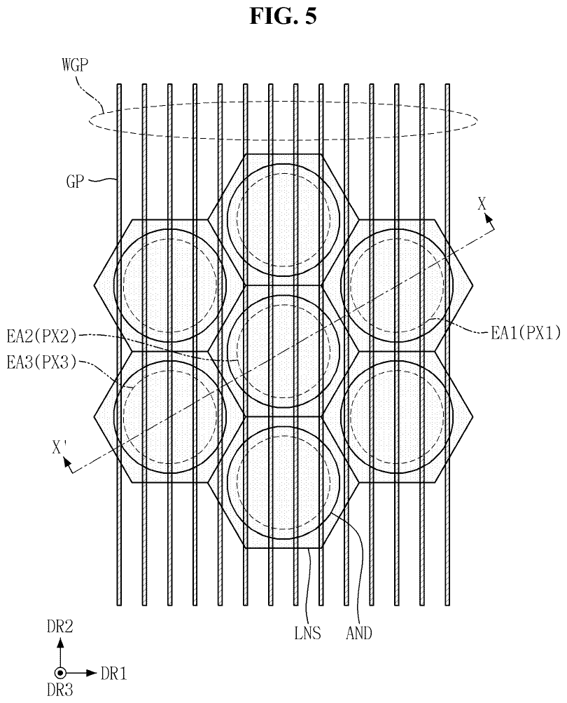

FIG. 5 is a layout diagram showing embodiments of the display area of FIG. 4.

Referring to FIG. 5, each of the plurality of unit pixels UPX may include a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area, and the unit emission area UEA may include the first emission area EA1, the second emission area EA2, and the third emission area EA3 described above.

Each of the plurality of pixels PX may include the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or irregular planar shape, but the shape of each of the emission areas EA1, EA2, and EA3 is not limited thereto.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have, in a plan view, a hexagonal shape formed of six straight lines as shown in FIG. 5, but the embodiment of the present specification is not limited thereto. The first emission area EA1, the second emission area EA2, and the third emission area EA3 may have a polygonal shape other than a hexagon, a circular shape, an elliptical shape, or an atypical shape in a plan view in another embodiment. As used herein, the “plan view” is a view in thickness direction (i.e., DR3) of the substrate SSUB (See FIG. 6).

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 380 nanometers (nm) to about 480 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is exemplified in FIG. 5 that each of the plurality of pixels PX includes three emission areas EA1, EA2, and EA3, but the embodiment of the present specification is not limited thereto. For another example, each of the plurality of pixels PX may include four emission areas.

In addition, the disposition of the emission areas of the plurality of pixels PX is not limited to that illustrated in FIG. 5. For example, the emission areas of the plurality of pixels PX may be disposed in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged side by side as shown in FIG. 6.

FIG. 6 is a cross-sectional view illustrating an example of the display panel 100 taken along line X-X′ of FIG. 5.

Referring to FIG. 6, the display panel 100 may include a semiconductor backplane SBP, a light emitting element backplane EBP, a display element layer EML, an encapsulation layer TFE, and an optical layer OPL. The semiconductor backplane SBP and the light emitting element backplane EBP may be collectively referred to as a “substrate” of the display panel 100.

The semiconductor backplane SBP may include the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

A first semiconductor insulating film SINS1 may be disposed on the semiconductor substrate SSUB. The first semiconductor insulating film SINS1 may be formed of silicon carbonitride (SiCN) or a silicon oxide (SiOx)-based inorganic film, but the embodiment of the present specification is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the embodiment of the present specification is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through holes penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the embodiment of the present specification is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating films INS1 to INS9. In addition, the light emitting element backplane EBP may include a plurality of insulating films INS1 to INS11 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first pixel PX1 shown in FIG. 4. For example, the first to sixth transistors T1 to T6 are merely disposed on the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light emitting element LE is also accomplished through the first to eighth conductive layers ML1 to ML8.

The first insulating film INS1 may be disposed on the semiconductor backplane SBP. Each of the first vias VA1 may penetrate the first insulating film INS1 to be connected to the contact terminal CTE exposed from the semiconductor backplane SBP. Each of the first conductive layers ML1 may be disposed on the first insulating film INS1 and may be connected to the first via-connector VA1.

The second insulating film INS2 may be disposed on the first insulating film INS1 and the first conductive layers ML1. Each of the second vias VA2 may penetrate the second insulating film INS2 and be connected to the exposed first conductive layer ML1. Each of the second conductive layers ML2 may be disposed on the second insulating film INS2 and may be connected to the second via-connector VA2.

The third insulating film INS3 may be disposed on the second insulating film INS2 and the second conductive layers ML2. Each of the third vias VA3 may penetrate the third insulating film INS3 and be connected to the exposed second conductive layer ML2. Each of the third conductive layers ML3 may be disposed on the third insulating film INS3 and may be connected to the third via-connector VA3.

A fourth insulating film INS4 may be disposed on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be disposed on the fourth insulating film INS4 and may be connected to the fourth via-connector VA4.

A fifth insulating film INS5 may be disposed on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be disposed on the fifth insulating film INS5 and may be connected to the fifth via-connector VA5.

A sixth insulating film INS6 may be disposed on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be disposed on the sixth insulating film INS6 and may be connected to the sixth via-connector VA6.

A seventh insulating film INS7 may be disposed on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be disposed on the seventh insulating film INS7 and may be connected to the seventh via-connector VA7.

An eighth insulating film INS8 may be disposed on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be disposed on the eighth insulating film INS8 and may be connected to the eighth via-connector VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating films INS1 to INS8 may be formed of a silicon oxide (SiOx)-based inorganic film, but the embodiment of the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via-connector VA1, the second via-connector VA2, the third via-connector VA3, the fourth via-connector VA4, the fifth via-connector VA5, and the sixth via-connector VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 angstroms (Å); the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via-connector VA1, the second via-connector VA2, the third via-connector VA3, the fourth via-connector VA4, the fifth via-connector VA5, and the sixth via-connector VA6 may be approximately 1150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via-connector VA7 and the thickness of the eighth via-connector VA8, respectively. The thickness of each of the seventh via-connector VA7 and the eighth via-connector VA8 may be larger than the thickness of the first via-connector VA1, the thickness of the second via-connector VA2, the thickness of the third via-connector VA3, the thickness of the fourth via-connector VA4, the thickness of the fifth via-connector VA5, and the thickness of the sixth via-connector VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via-connector VA7 and the eighth via-connector VA8 may be approximately 6000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the embodiment of the present specification is not limited thereto.

Each of the ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via-connector VA9 may be approximately 16500 Å.

The display element layer EML may be disposed on the light emitting element backplane EBP. The display element layer EML may include light emitting elements LE each including a reflective electrode layer RL, tenth and eleventh insulating films INS10 and INS11, a tenth via-connector VA10, a first electrode AND, a light emitting stack ES, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 6.

Each of the first reflective electrodes RL1 may be disposed on the ninth insulating film INS9, and may be connected to the ninth via-connector VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

The fourth reflective electrodes RL4 may be disposed on the third reflective electrodes RL3, respectively. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RLA. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

A tenth insulating film INS10 may be disposed on the ninth insulating film INS9. The tenth insulating film INS10 may be disposed between the reflective electrode layers RL adjacent to each other in a horizontal direction. The tenth insulating film INS10 may be disposed on the reflective electrode layer RL in the third pixel PX3. The tenth insulating film INS10 may be formed of a silicon oxide (SiOx)-based inorganic film, but the embodiment of the present specification is not limited thereto.

An eleventh insulating film INS11 may be disposed on the tenth insulating film INS10 and the reflective electrode layer RL. The eleventh insulating film INS11 may be formed of a silicon oxide (SiOx)-based inorganic film, but the embodiment of the present specification is not limited thereto. The tenth insulating film INS10 and the eleventh insulating film INS11 may be an optical auxiliary layer through which light reflected by the reflective electrode layer RL passes, among light emitted from the light emitting elements LE in another embodiment.

To match the resonance distance of the light emitted from the light emitting elements LE in at least one of the first pixel PX1, the second pixel PX2, or the third pixel PX3, the tenth insulating film INS10 and the eleventh insulating film INS11 may not be disposed under the first electrode AND of the first pixel PX1. The first electrode AND of the first pixel PX1 may be directly disposed on the reflective electrode layer RL. The eleventh insulating film INS11 may be disposed under the first electrode AND of the second pixel PX2. The tenth insulating film INS10 and the eleventh insulating film INS11 may be disposed under the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating film INS10 and the eleventh insulating film INS11 may be set in each of the first pixel PX1, the second pixel PX2, and the third pixel PX3. For example, it is illustrated in FIG. 6 that the distance between the first electrode AND and the reflective electrode layer RL in the third pixel PX3 is larger than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is larger than the distance between the first electrode AND and the reflective electrode layer RL in the first pixel PX1, but the specification of the present disclosure is not limited thereto.

In addition, although the tenth insulating film INS10 and the eleventh insulating film INS11 are illustrated in the embodiment of the present specification, a twelfth insulating film disposed under the first electrode AND of the first pixel PX1 may be added. In this case, the eleventh insulating film INS11 and a twelfth insulating film INS12 may be disposed under the first electrode AND of the second pixel PX2, and the tenth insulating film INS10, the eleventh insulating film INS11, and the twelfth insulating film INS12 may be disposed under the first electrode AND of the third pixel PX3.

Each of the tenth vias VA10 may penetrate the tenth insulating film INS10 and/or the eleventh insulating film INS11 in the second pixel PX2 and the third pixel PX3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via-connector VA10 in the second pixel PX2 may be smaller than the thickness of the tenth via-connector VA10 in the third pixel PX3.

The first electrode AND of each of the light emitting elements LE may be disposed on the tenth insulating film INS10 and connected to the tenth via-connector VA10. The first electrode AND of each of the light emitting elements LE may be connected to the drain region DA or source region SA of the pixel transistor PTR through the tenth via-connector VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a portion of the first electrode AND of each of the light emitting elements LE. The pixel defining film PDL may cover the edge of the first electrode AND of each of the light emitting elements LE. The pixel defining film PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first pixel PX1 to emit light. The second emission area EA2 may be defined as an area in which the first electrode AND, the light emitting stack ES, and the second electrode CAT are sequentially stacked in the second pixel PX2 to emit light. The third emission area EA3 may be defined as an area in which the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the embodiment of the present specification is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic film TFE1 from being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. The tenth insulating film INS10 may be partially recessed at each of the plurality of trenches TRC.

At least one trench TRC may be disposed between adjacent pixels PX1, PX2, and PX3. Although FIG. 6 illustrates that two trenches TRC are disposed between adjacent pixels PX1, PX2, and PX3, the embodiment of the present specification is not limited thereto.

The light emitting stack ES may include a plurality of intermediate layers. FIG. 6 illustrates that the light emitting stack ES has a three-tandem structure including a first stack layer IL1, a second stack layer IL2, and a third stack layer IL3, but the embodiment of the present specification is not limited thereto. For another example, the light emitting stack ES may have a two-tandem structure including two intermediate layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the second color, and the third stack layer IL3 that emits light of the third color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the second color, and a second electron transport layer are sequentially stacked. The third stack layer IL3 may have a structure in which a third hole transport layer, a third organic light emitting layer that emits light of the third color, and a third electron transport layer are sequentially stacked. In this case, the light emitting stack may emit white light in which the light of the first color (e.g., red light) from the first organic light emitting layer, the light of the second color (e.g., green light) from the second organic light emitting layer, and the light of the third color (e.g., blue light) from the third organic light emitting layer are mixed. Accordingly, the white light may be emitted from each of the first emission area EA1, the second emission area EA2, and the third emission area EA3. Here, the white light having passed through the first emission area EA1 may be incident on a first color filter CF1, the white light having passed through the second emission area EA2 may be incident on a second color filter CF2, and the white light having passed through the third emission area EA3 may be incident on a third color filter CF3.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be separated between adjacent pixels PX1, PX2, and PX3. The second stack layer IL2 may be disposed on the first stack layer IL1. Due to the trench TRC, the second stack layer IL2 may be separated between adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining film PDL.

The number of the stack layers IL1, IL2, and IL3 that emit different lights is not limited to that shown in FIG. 6. For example, the light emitting stack ES may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, FIG. 6 illustrates that the first to third stack layers IL1, IL2, and IL3 are all disposed in the first emission area EA1, the second emission area EA2, and the third emission area EA3, but the embodiment of the present specification is not limited thereto. For another example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (“TCO”) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic film TFE1 and TFE2 to prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic layer TFE2 may be formed of titanium oxide (TiOx) or aluminum oxide (AlOx), but the embodiment of the present specification is not limited thereto. The second encapsulation inorganic film TFE2 may be formed by an atomic layer deposition (“ALD”) process. The thickness of the second encapsulation inorganic film TFE2 may be smaller than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, or polyimide resin.

The optical layer OPL may include a color filter layer CFL, a lens layer LSL, a filling layer FIL, a cover layer CVL, a phase retardation layer QWP, and a wire grid polarizer WGP.

The color filter layer CFL may include the plurality of color filters CF1, CF2, and CF3. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 (e.g., red light emission area) of the first pixel PX1. The first color filter CF1 may transmit light of the first color, e.g., light of a red wavelength band. The red wavelength band may be approximately 600 nm to 750 nm. Thus, the first color filter CF1 may transmit light of the first color among light emitted from the first emission area EA1.

The second color filter CF2 may overlap the second emission area EA2 (e.g., green light emission area) of the second pixel PX2. The second color filter CF2 may transmit light of the second color, e.g., light of a green wavelength band. The green wavelength band may be approximately 480 nm to 560 nm. Thus, the second color filter CF2 may transmit light of the second color among light emitted from the second emission area EA2.

The third color filter CF3 may overlap the third emission area EA3 (e.g., blue light emission area) of the third pixel PX3. The third color filter CF3 may transmit light of the third color, e.g., light of a blue wavelength band. The blue wavelength band may be approximately 370 nm to 460 nm. Thus, the first color filter CF1 may transmit light of the first color among light emitted from the first emission area EA1.

The lens layer LSL may be disposed on the color filter layer CFL. The lens layer LSL may include a plurality of lenses LNS. The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the lens layer LSL. For example, the filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL and may face the light emitting element backplane EBP. The cover layer CVL may be a glass substrate or a polymer resin. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The phase retardation layer QWP (or retardation plate, or retardation film) may be disposed on the color filter layer CFL. The phase retardation layer QWP may be a λ/4 plate (quarter-wave plate), but the embodiment of the present specification is not limited thereto. The phase retardation layer QWP may be formed, for example, by a coating method. In one embodiment, the phase retardation layer QWP may be formed by coating and polymerizing a liquid crystal material including reactive mesogen (“RM”).

The wire grid polarizer WGP may be disposed on the phase retardation layer QWP, may be disposed, for example, between the phase retardation layer QWP and the lens layer LSL. The wire grid polarizer WGP and the phase retardation layer QWP may constitute a polarization member. For example, the polarization member according to one embodiment may include the phase retardation layer QWP and the wire grid polarizer WGP.

The wire grid polarizer WGP may include a plurality of grid patterns GP. As shown in FIG. 5, each grid pattern GP may have a rectangular shape extending along the second direction DR2. Further, as shown in FIG. 5, the grid patterns GP may be arranged along the first direction DR1. The grid patterns GP may be disposed to be spaced apart from each other in the first direction DR1. The wire grid polarizer WGP may contain at least one of aluminum (Al), silver (Ag), or gold (Au). For example, each of the grid patterns GP may be made of a material containing at least one of aluminum (Al), silver (Ag), or gold (Au).

The wire grid polarizer WGP may transmit light of a specific polarization direction while reflecting light of another polarization direction to recycle it. This wire grid polarizer WGP is useful as a reflective polarizer because it exhibits higher polarization separation performance than other polarizers. For example, the wire grid polarizer WGP is a device that creates polarization using a conductive wire grid, and may have a structure in which a plurality of wires made of a conductive material are periodically arranged in parallel to each other in a nano size on the phase retardation layer QWP to form the grid patterns GP. In the wire grid polarizer WGP including the plurality of grid patterns GP, if the period of the grid pattern GP is less than the wavelength of the incident light, diffraction of the incident light does not occur. Thus, the wire grid polarizer WGP may transmit, among the incident light, a component having a vibration direction orthogonal to the conductive grid pattern GP, such as transverse magnetic (“TM”) polarization (e.g., a P wave), while reflecting a component having a vibration direction parallel to the grid pattern GP, such as transverse electric (“TE”) polarization (e.g., a S wave). In other words, when the arrangement period of the grid pattern GP is shorter than the wavelength of the electromagnetic wave incident on the wire grid polarizer WGP, the wire grid polarizer WGP may reflect a polarization component (e.g., S wave) parallel to the grid pattern GP, while transmitting a polarization component (e.g., P wave) orthogonal to the grid pattern GP. Since the wire grid polarizer WGP uses the grid pattern GP made of metal, light reflection efficiency thereof is very high. Thus, as the reflected light can be re-reflected, the light can be recycled to make all lights into one polarized light.

According to one embodiment, the wire grid polarizer WGP may have the grid pattern GP of a relatively larger pitch in the third emission area EA3 through which blue light is transmitted (or the third emission area EA3 overlapping the blue color filter F3), and may have the grid pattern GP of a relatively smaller pitch in the first emission area EA1 or the second emission area EA2. In other words, the grid patterns GP of the wire grid polarizer WGP may have a smaller pitch in the above-described third emission area EA3 than in the first emission area or the second emission area EA2.

According to one embodiment, the grid patterns GP of the wire grid polarizer WGP that receives short-wavelength light, such as blue light, may have a relatively smaller pitch (or interval). For example, when the pitch of the grid patterns GP of the first pixel PX1 providing red light is defined as a first pitch P1 (or a first interval), the pitch of the grid patterns GP of the second pixel PX2 providing green light is defined as a second pitch P2 (or a second interval), and the pitch of the grid patterns GP of the third pixel PX3 providing blue light is defined as a third pitch P3 (or a third interval), the third pitch P3 (or the third interval) may be smaller than the first pitch P1 (or the first interval) or the second pitch P2 (or the second interval). In one embodiment, the first pitch P1 (or the first interval) and the second pitch P2 (or the second interval) may be the same.

In other words, when the pitch of the grid patterns GP disposed on the first color filter CF1 transmitting red light is defined as the first pitch P1 (or the first interval), the pitch of the grid patterns GP disposed on the second color filter CF2 transmitting green light is defined as the second pitch P2 (or the second interval), and the pitch of the grid patterns GP disposed on the third color filter CF3 transmitting blue light is defined as the third pitch P3 (or the third interval), the third pitch P3 (or the third interval) may be smaller than the first pitch P1 (or the first interval) or the second pitch P2 (or the second interval). In one embodiment, the first pitch P1 (or the first interval) and the second pitch P2 (or the second interval) may be the same. Accordingly, transmittance of short-wavelength light, such as blue light, may be improved. In other words, as the transmittance of the short-wavelength light is improved, the transmittance of the blue light can be maintained almost equal to those of other colors, such as the transmittance of the green light and the transmittance of the red light. Accordingly, the luminance balance between the blue light, the green light and the red light may be improved.

According to one embodiment, the first pitch P1 may be in the range of 100 nm to 150 nm, the second pitch P2 may be in the range of 100 nm to 150 nm, and the third pitch P3 may be in the range of 50 nm to 90 nm.

According to one embodiment, at least one of the grid patterns GP of the wire grid polarizer WGP may have a thickness TK of 100 nm to 300 nm. As another example, at least one of the grid patterns GP of the wire grid polarizer WGP may have a thickness TK of 100 nm to 200 nm. According to one embodiment, all the grid patterns GP of the wire grid polarizer WGP may have the same thickness TK.

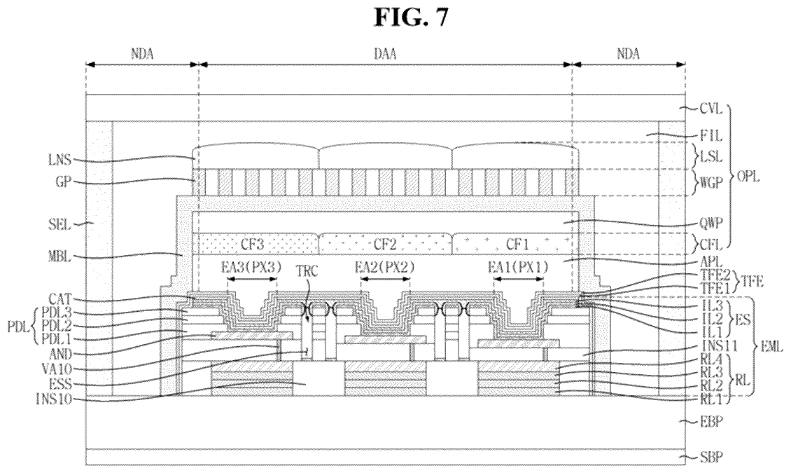

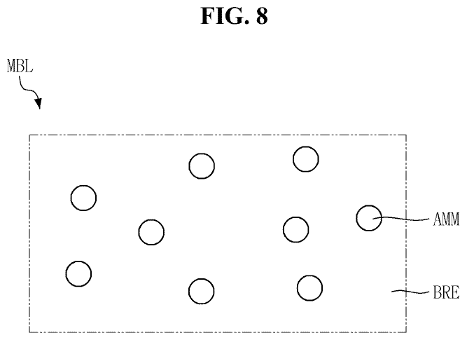

FIG. 7 is a cross-sectional view illustrating a cross section of the display panel according to one embodiment. FIG. 8 is a cross-sectional view schematically showing a barrier layer according to one embodiment.

Referring to FIG. 7, the display panel 100 according to one embodiment may include the semiconductor backplane SBP, the light emitting element backplane EBP, the display element layer EML, the encapsulation layer TFE, and the optical layer OPL, and may further include the barrier layer MBL covering the phase retardation layer QWP.

The semiconductor backplane SBP and the light emitting element backplane EBP may function as a base substrate of the display panel 100 to form a base of the display panel 100. The display element layer EML may be disposed on the light emitting element backplane EBP. The display element layer EML may be disposed in the display area DAA of the display panel 100, and at least a part thereof may extend to the non-display area NDA.

The encapsulation layer TFE may be disposed on the display element layer EML to seal the display element layer EML. The encapsulation layer TFE may extend from the display area DAA to the non-display area NDA. The encapsulation layer TFE may cover the side surface of the display element layer EML from above the display element layer EML, for example, from above the cathode electrode CAT, and extend to the light emitting element backplane EBP. In some embodiments, the encapsulation layer TFE may be in contact with the side surfaces of the light emitting stack ES (FIG. 6), the pixel defining film PDL (FIG. 6), the tenth insulating layer INS10 (FIG. 6), and the eleventh insulating layer INS11 (FIG. 6), and may be in contact with the ninth insulating layer INS9 (FIG. 6) of the light emitting element backplane EBP.

The organic film APL may be disposed on the encapsulation layer TFE, and the color filter layer CFL may be disposed on the organic film APL. The organic film APL and the color filter layer CFL may be disposed in the entire display area DAA and may extend to the non-display area NDA.

The phase retardation layer QWP may be disposed on the color filter layer CFL. The phase retardation layer QWP may be disposed in the entire display area DAA on the color filter layer CFL, and a part thereof may extend to the non-display area NDA. Although FIG. 7 shows that the phase retardation layer QWP is disposed on the top surface of the color filter layer CFL, the present disclosure is not limited thereto, and the phase retardation layer QWP may cover the side surface of the color filter layer CFL in another embodiment.

Meanwhile, the materials included in the phase retardation layer QWP may be vulnerable to moisture. For example, the phase difference value or luminance characteristics of the phase retardation layer QWP may decrease in a high temperature and high humidity environment.

In the present embodiment, the barrier layer MBL that protects the phase retardation layer QWP is included, so moisture permeating into the phase retardation layer QWP may be blocked.

Specifically, the barrier layer MBL may be disposed on the phase retardation layer QWP. The barrier layer MBL may be disposed in the entire display area DAA of the display panel 100 and may extend to the non-display area NDA.

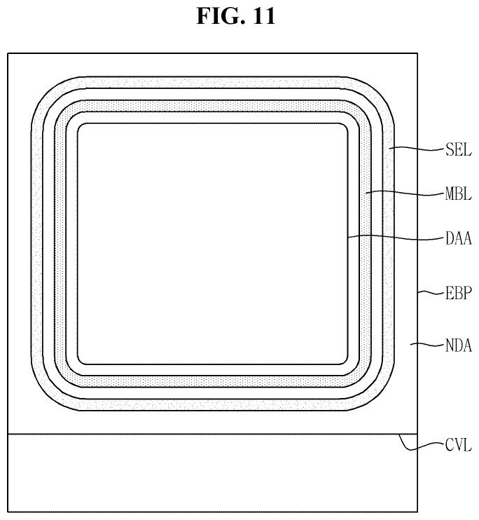

The barrier layer MBL may cover the display element layer EML, the encapsulation layer TFE, the organic film APL, the color filter layer CFL, and the phase retardation layer QWP. For example, the barrier layer MBL may be in direct contact with the top and side surfaces of the phase retardation layer QWP, the side surface of the color filter layer CFL, the side surfaces of the organic film APL, and the side surface of the encapsulation layer TFE, and may be formed in a closed loop shape to surround them (like FIG. 11) in a plan view. In addition, the barrier layer MBL may be in contact with the bottom surface of the wire grid polarizer WGP. The barrier layer MBL may extend to the light emitting element backplane EBP to be in contact with the top surface of the light emitting element backplane EBP. For example, the barrier layer MBL may be in direct contact with the ninth insulating layer INS9 (FIG. 6) of the light emitting element backplane EBP.

The barrier layer MBL may block moisture from permeating into the display element layer EML, the organic film APL, the color filter layer CFL, and the phase retardation layer QWP from the outside. For example, the barrier layer MBL may adsorb or remove moisture.

Referring to FIG. 8, the barrier layer MBL may include a base resin BRE and a moisture absorbent material AMM.

The base resin BRE is a resin forming the base of the barrier layer MBL, and may include, by way of non-limiting example, a UV curable resin. In some embodiments, the UV curable resin may be an acrylic resin, an epoxy resin, a polyimide resin, or a polyethylene resin.

The moisture absorbent material AMM may adsorb or remove moisture permeating from the outside through a physical or chemical reaction. The moisture absorbent material AMM may include at least one of metal salt or metal oxide. In some embodiments, the metal oxide may be lithium oxide (Li₂O), aluminum oxide (Al₂O₃), sodium oxide (Na₂O), barium oxide (BaO), calcium oxide (CaO), magnesium oxide (MgO), or the like. The metal salt may be sulfate such as lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂) or nickel sulfate (NiSO₄), metal halides such as calcium chloride (CaCl₂)), magnesium chloride (MgCl₂), strontium chloride (SrCl₂), yttrium chloride (YCl₃), copper chloride (CuCl₂), cesium fluoride (CsF), tantalum fluoride (TaF₅), niobium fluoride (NbF₅), lithium bromide (LiBr), calcium bromide (CaBr₂), cesium bromide (CeBr₃), selenium bromide (SeBr₄), vanadium bromide (VBr₃), magnesium bromide (MgBr₂), barium iodide (BaI₂) or magnesium iodide (MgI₂), barium perchlorate (Ba(ClO₄)₂), magnesium perchlorate (Mg(ClO₄)₂), or the like. However, the present disclosure is not limited thereto, and a material such as phosphorus oxide (P₂O₅) may be included in another embodiment.

The particle diameter of the moisture absorbent material AMM may be in the range of 10 nm to 1000 nm. In some embodiments, the moisture absorbent material AMM may be made of the same material or different materials. In some embodiments, the moisture absorbent material AMM may have the same particle diameter or different particle diameters.

The moisture absorbent material AMM may be included in an amount of 1 weight percentage (wt %) to 50 wt % with respect to the total barrier layer MBL. When the content of the moisture absorbent material AMM is within the above-specified range, moisture absorption characteristics may be imparted to the barrier layer MBL while maintaining the processability and the light transmittance of the barrier layer MBL.

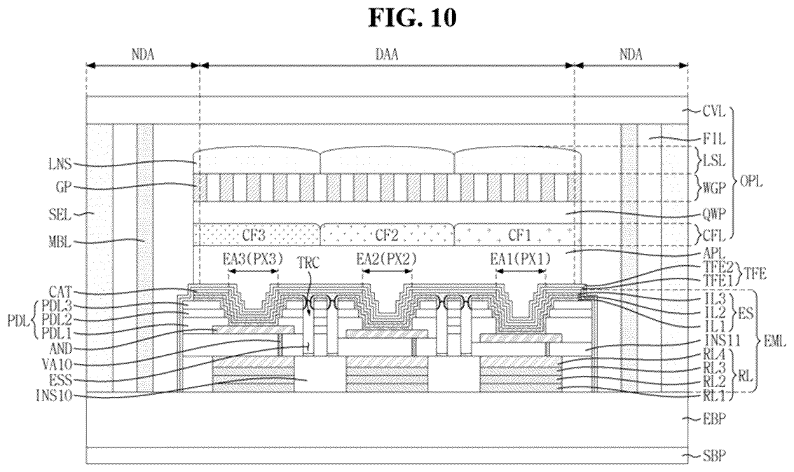

The thickness of the barrier layer MBL may be in the range of 0.1 micrometers (μm) to 5 μm. When the thickness of the barrier layer BML is within the above-specified range, moisture blocking characteristics may be ensured without significantly reducing the light transmittance of the display area DAA. Here, the thickness of the barrier layer MBL is a thickness of a portion of the barrier layer MBL in contact with the top surface of the phase retardation layer QWP measured in the third direction DR3, a thickness of a portion of the barrier layer MBL in contact with the side surface of the phase retardation layer QWP measured in a horizontal direction perpendicular to the third direction DR3 in FIG. 7, 9 or 12, or a thickness of a portion of the barrier layer MBL measured in a horizontal direction perpendicular to the third direction DR3 in FIG. 10.

The wire grid polarizer WGP may be disposed on the barrier layer MBL, and the lens layer LSL may be disposed on the wire grid polarizer WGP. The wire grid polarizer WGP may be directly disposed on the top surface of the barrier layer MBL, and the lens layer LSL may be directly disposed on the top surface of the wire grid polarizer WGP. The wire grid polarizer WGP and the lens layer LSL are disposed in the entire display area DAA and may extend to the non-display area NDA.

The cover layer CVL may be disposed to face the light emitting element backplane EBP. The cover layer CVL may be coupled to the light emitting element backplane EBP through a coupling member SEL to form the display panel 100. The coupling member SEL may be disposed in the non-display area NDA of the display panel 100 to couple the cover layer CVL to the light emitting element backplane EBP.

The filling layer FIL may be disposed in a space within the display panel 100 sealed by the light emitting element backplane EBP, the cover layer CVL, and the coupling member SEL. The filling layer FIL may be disposed in direct contact with the lens layer LSL, the wire grid polarizer WGP, and the barrier layer MBL.

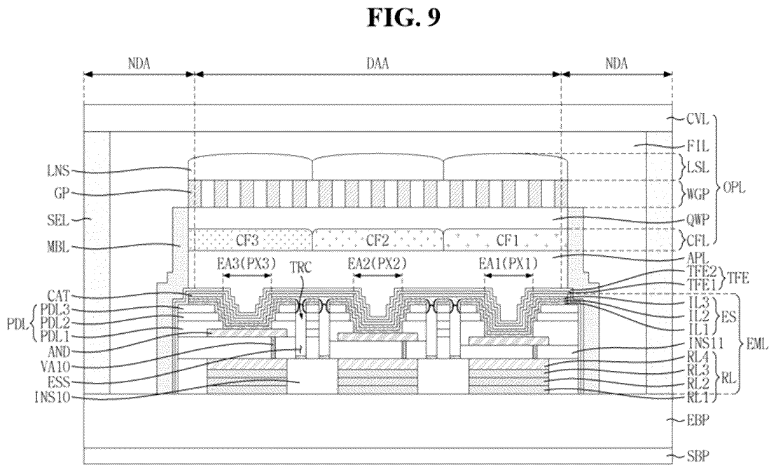

FIG. 9 is a cross-sectional view showing an example of a display panel according to another embodiment.

Referring to FIG. 9, the present embodiment differs from the embodiment of FIGS. 7 and 8 described above in that the barrier layer MBL is disposed in the non-display area NDA and does not cover the top surface of the phase retardation layer QWP. In the following description, redundant description of the above-described embodiments will be omitted while focusing on differences.

The barrier layer MBL may be disposed on the side surface of the phase retardation layer QWP. For example, the barrier layer MBL may be in contact with the side surface of the phase retardation layer QWP and may not cover the top surface of the phase retardation layer QWP.

According to one embodiment, the barrier layer MBL may extend from the side surface of the phase retardation layer QWP to the top surface of the light emitting element backplane EBP. For example, the barrier layer MBL may extend upwards from the light emitting element backplane EBP and may be disposed along the side surface of each of the display element layer EML, the encapsulation layer TFE, the organic film APL, the color filter layer CFL, and the phase retardation layer QWP. Accordingly, the barrier layer MBL may be in direct contact with the side surface of the display element layer EML, the side surface of the encapsulation layer TFE, the side surface of the organic film APL, the side surface of the color filter layer CFL, and the side surface of the phase retardation layer QWP.

As the barrier layer MBL is disposed along the side surfaces of the display element layer EML, the encapsulation layer TFE, the organic film APL, the color filter layer CFL, and the phase retardation layer QWP and is formed in a closed loop shape to surround them (like FIG. 11) in a plan view, the moisture from the outside may be effectively prevented from permeating into the side surfaces of the display element layer EML, the encapsulation layer TFE, the organic film APL, the color filter layer CFL, and the phase retardation layer QWP.

According to one embodiment, the barrier layer MBL may be disposed in the non-display area NDA without overlapping the display area DAA. For example, the barrier layer MBL may not overlap the phase retardation layer QWP in the third direction DR3. Since the top surface of the phase retardation layer QWP corresponds to the display area DAA in which light emitted from the display element layer EML is emitted to the cover layer CVL, the light transmittance of the display panel 100 may be improved by disposing the barrier layer MBL so as not to overlap the top surface of the phase retardation layer QWP in a plan view.

FIG. 10 is a cross-sectional view showing an example of a display panel according to still another embodiment. FIG. 11 is a plan view showing an example of a display panel according to still another embodiment of FIG. 10.

Referring to FIGS. 10 and 11, the present embodiment differs from the above-described embodiments of FIGS. 7 to 9 in that the barrier layer MBL is disposed in the non-display area NDA and is not in contact with the layers disposed in the display area DAA.

According to one embodiment, the barrier layer MBL may be disposed in the non-display area NDA. The barrier layer MBL may be disposed on the light emitting element backplane EBP in the non-display area NDA. The bottom surface of the barrier layer MBL may be in contact with the top surface of the light emitting element backplane EBP, and the top surface of the barrier layer MBL may be in contact with the bottom surface of the cover layer CVL.

The barrier layer MBL may not be disposed in the display area DAA and may not overlap the display area DAA. The barrier layer MBL may be disposed to be spaced apart from the display element layer EML, the encapsulation layer TFE, the organic film APL, the color filter layer CFL, the phase retardation layer QWP, the wire grid polarizer WGP, and the lens layer LSL disposed in the display area DAA.

The barrier layer MBL may be disposed to surround the display area DAA in a plan view. For example, the barrier layer MBL may be formed in a closed loop shape to surround the display area DAA. The barrier layer MBL may prevent moisture from permeating into the display area DAA by coupling the light emitting element backplane EBP to the cover layer CVL while surrounding the display area DAA.

The filling layer FIL may be disposed in a space defined by the light emitting element backplane EBP, the barrier layer MBL, and the cover layer CVL. Although FIG. 10 shows that the filling layer FIL is not disposed between the barrier layer MBL and the coupling member SEL, the present disclosure is not limited thereto, and the filling layer FIL may also be disposed between the barrier layer MBL and the coupling member SEL in another embodiment.

The coupling member SEL may be disposed in the non-display area NDA, and may couple the light emitting element backplane EBP to the cover layer CVL. The coupling member SEL may be disposed to surround the display area DAA and the barrier layer MBL in a plan view. The coupling member SEL may be spaced apart from the barrier layer MBL, and the barrier layer MBL may be disposed between the display area DAA and the coupling member SEL in a plan view.

According to one embodiment, as the barrier layer MBL is disposed in the non-display area NDA and couples the cover layer CVL to the light emitting element backplane EBP, moisture permeation into the display area DA may be blocked, and a decrease in the light transmittance of the display area DA may be suppressed. In addition, the barrier layer MBL may improve the coupling strength between the cover layer CVL and the light emitting element backplane EBP.

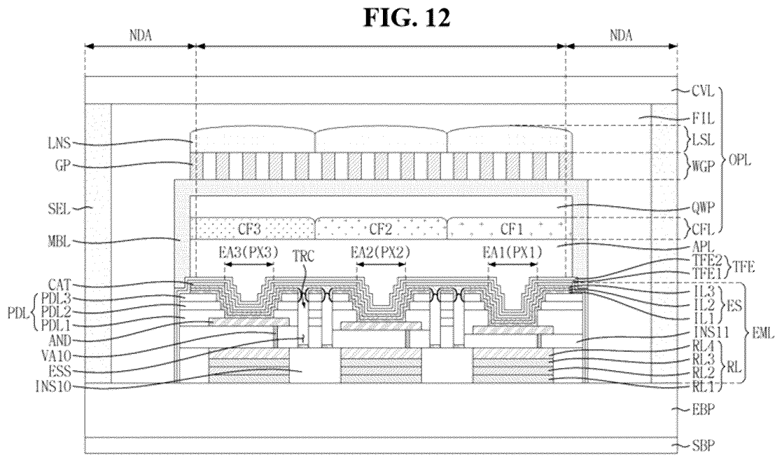

FIG. 12 is a cross-sectional view showing a display panel according to still another embodiment.

Referring to FIG. 12, the present embodiment differs from the above-described embodiment of FIG. 7 in that the barrier layer MBL is disposed on the encapsulation layer TFE while covering the phase retardation layer QWP.

According to one embodiment, the barrier layer MBL may be disposed between the phase retardation layer QWP and the wire grid polarizer WGP. The barrier layer MBL may extend downwards while covering the phase retardation layer QWP on the phase retardation layer QWP. The barrier layer MBL may extend to the top surface of the encapsulation layer TFE along the side surface of the phase retardation layer QWP, the side surface of the color filter layer CFL, the side surface of the organic film APL, and the side surface of the encapsulation layer TFE. The barrier layer MBL may be in contact with the top surface of the encapsulation layer TFE. For example, unlike in FIG. 7, the barrier layer MBL may be disposed to be spaced apart from the light emitting element backplane EBP.

As the barrier layer MBL is in contact with the encapsulation layer TFE, the organic film APL, the color filter layer CFL, and the phase retardation layer QWP disposed between the barrier layer MBL and the encapsulation layer TFE may be sealed by the barrier layer MBL and the encapsulation layer TFE. Therefore, moisture from the outside is blocked by the barrier layer MBL, so that the organic film APL, the color filter layer CFL, and the phase retardation layer QWP may be protected from the moisture.

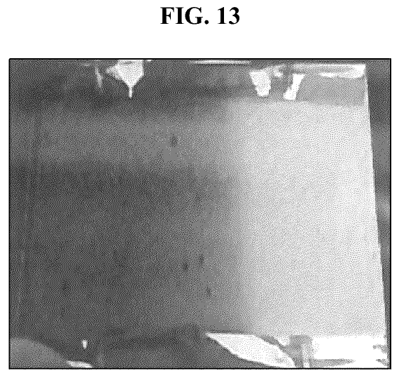

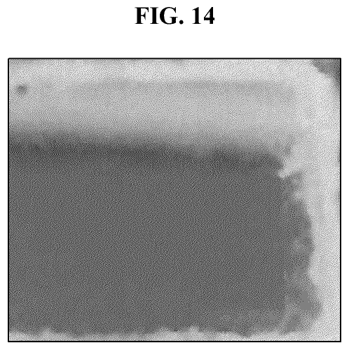

FIG. 13 presents an image after a reliability test of a display panel according to a comparative example, and FIG. 14 provides an image after a reliability test of a display panel according to one embodiment.

As the comparative example, a display panel having no barrier layer was manufactured, and as the embodiment, a display panel of FIG. 7 having a barrier layer was manufactured. A reliability test was performed on the display panels manufactured according to the comparative example and the embodiment. In the reliability test, the display panels were exposed to an environment of a temperature of 85° C. and humidity of 85% for 100 hours. Thereafter, a phase difference, black luminance, and haze of each display panel were observed.

First, the display panel according to the comparative example without having a barrier layer has experienced changes in phase difference and black luminance, whereas the display panel according to the embodiment having a barrier layer has experienced no change in phase difference and black luminance.

In addition, haze was observed in the display panel according to the comparative example as shown in FIG. 13, whereas no haze was observed in the display panel according to the embodiment as shown in FIG. 14.

As described above, it was confirmed that the display panel equipped with the barrier layer capable of blocking moisture can prevent changes in phase difference and black luminance, and can also prevent occurrence of haze.

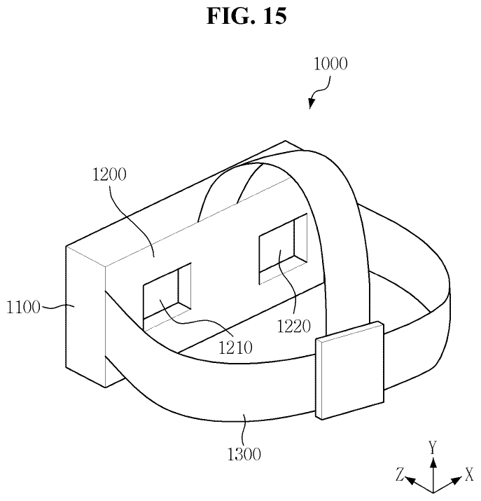

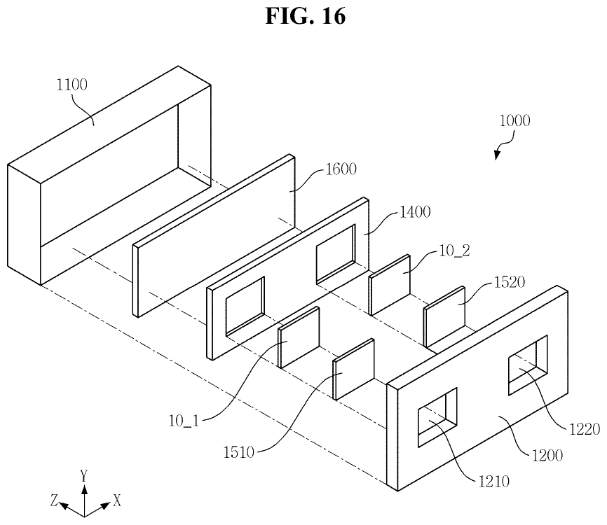

FIG. 15 is a perspective view illustrating a head mounted display according to one embodiment. FIG. 16 is an exploded perspective view illustrating an example of the head mounted display of FIG. 15.

Referring to FIGS. 15 and 16, a head mounted display 1000 according to one embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 15 and 16 illustrate that the first eyepiece 1210 and the second eyepiece 1220 are disposed separately, but the embodiment of the present specification is not limited thereto. The first eyepiece 1210 and the second eyepiece 1220 may be combined into one in another embodiment.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

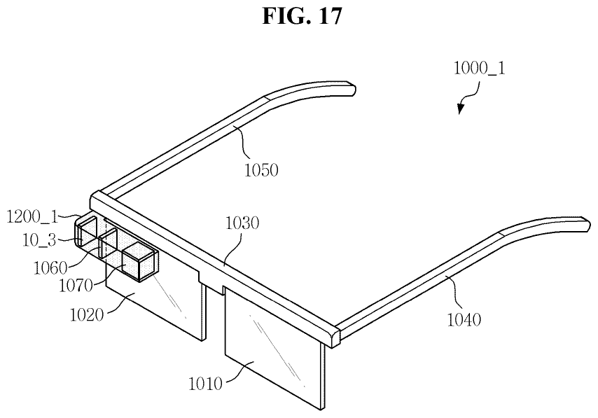

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented to be lightweight and compact, the head mounted display 1000 may be provided with, as shown in FIG. 17, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (“USB”) terminal, a display port, or a high-definition multimedia interface (“HDMI”) terminal, and the wireless communication module may be a 5G communication module, a 4G communication module, a Wi-Fi module, or a Bluetooth module.

FIG. 17 is a perspective view illustrating a head mounted display according to one embodiment.

Referring to FIG. 17, a head mounted display 1000_1 according to one embodiment may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 17 illustrates that the display device housing 1200_1 is disposed at the right end of the support frame 1030, but the embodiment of the present specification is not limited thereto. For another example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

The display device according to one embodiment of the present disclosure can be applied to various electronic devices. The electronic device according to the one embodiment of the present disclosure includes the display device described above, and may further include modules or devices having additional functions in addition to the display device.

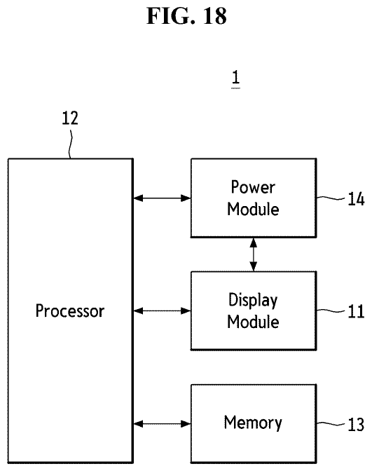

FIG. 18 is a block diagram of an electronic device according to one embodiment of the present disclosure.

Referring to FIG. 18, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

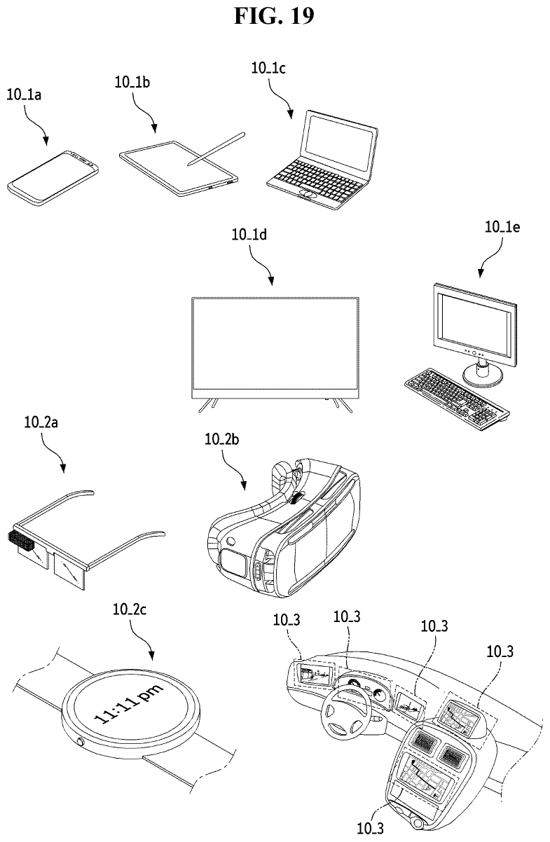

FIG. 19 is a schematic diagram of an electronic device according to various embodiments of the present disclosure.

Referring to FIG. 19, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate;
a display element layer disposed on the substrate, and comprising a first electrode, a light emitting layer, and a second electrode;
a phase retardation layer disposed on the display element layer;
a barrier layer disposed on a side surface of the phase retardation layer; and
a wire grid polarizer disposed on the phase retardation layer,
wherein the barrier layer contains a moisture absorbent material.

2. The display device of claim 1, wherein the barrier layer is in contact with the side surface of the phase retardation layer, and extends to a top surface of the substrate.

3. The display device of claim 1, wherein the barrier layer is disposed to extend further between the phase retardation layer and the wire grid polarizer, and the barrier layer covers the phase retardation layer.

4. The display device of claim 3, wherein the barrier layer is in contact with a top surface of the phase retardation layer and a bottom surface of the wire grid polarizer.

5. The display device of claim 1, further comprising:
an encapsulation layer disposed on the display element layer, and covering the display element layer; and
a color filter layer disposed on the encapsulation layer,
wherein the phase retardation layer is disposed on the color filter layer.

6. The display device of claim 5, wherein the barrier layer is in contact with the side surface of the phase retardation layer, a side surface of the color filter layer, and a side surface of the encapsulation layer.

7. The display device of claim 6, wherein the barrier layer is disposed to extend further between the phase retardation layer and the wire grid polarizer, and the barrier layer covers the phase retardation layer and extends to a top surface of the encapsulation layer.

8. The display device of claim 1, wherein the barrier layer contains a base resin, and the moisture absorbent material is dispersed in the base resin.

9. The display device of claim 8, wherein the moisture absorbent material is contained in an amount of 1 weight percentage (wt %) to 50 wt % with respect to all materials in the barrier layer.

10. The display device of claim 1, wherein the moisture absorbent material contains at least one of metal salt or metal oxide.

11. The display device of claim 1, wherein a thickness of the barrier layer is 0.1 micrometers (μm) to 5 μm.

12. A display device comprising:
a substrate comprising a display area and a non-display area disposed around the display area;
a display element layer disposed on the display area of the substrate, and comprising a first electrode, a light emitting layer, and a second electrode;
a phase retardation layer disposed on the display element layer;
a wire grid polarizer disposed on the phase retardation layer;
a cover layer disposed on the wire grid polarizer, and facing the substrate;
a coupling member coupling the substrate to the cover layer; and
a barrier layer disposed in the non-display area of the substrate, and in contact with each of the substrate and the cover layer,
wherein the barrier layer contains a moisture absorbent material.

13. The display device of claim 12, wherein the coupling member is disposed in the non-display area, and the barrier layer is disposed between the display area and the coupling member in a plan view.

14. The display device of claim 12, wherein the barrier layer is disposed to surround the display area in a plan view, and is disposed to be spaced apart from the display element layer, the phase retardation layer, and the wire grid polarizer.

15. The display device of claim 12, wherein the barrier layer contains a base resin, and the moisture absorbent material is dispersed in the base resin.

16. The display device of claim 15, wherein the moisture absorbent material is contained in an amount of 1 wt % to 50 wt % with respect to all materials in the barrier layer.

17. An optical device comprising:
a display device; and
an optical path changing member disposed on the display device,
wherein the display device comprises:
a substrate;
a display element layer disposed on the substrate, and comprising a first electrode, a light emitting layer, and a second electrode;
a phase retardation layer disposed on the display element layer;
a barrier layer disposed on a side surface of the phase retardation layer; and
a wire grid polarizer disposed on the phase retardation layer,
wherein the barrier layer contains a moisture absorbent material.

18. The optical device of claim 17, wherein the barrier layer is in contact with the side surface of the phase retardation layer, and extends to a top surface of the substrate.

19. The optical device of claim 17, further comprising:
an encapsulation layer disposed on the display element layer, and covering the display element layer; and
a color filter layer disposed on the encapsulation layer,
wherein the phase retardation layer is disposed on the color filter layer.

20. The optical device of claim 17, wherein the moisture absorbent material is contained in an amount of 1 wt % to 50 wt % with respect to all materials in the barrier layer.

21. An electronic device, comprising:
a display device configured to provide an image;
a processor configured to provide an image data signal to the display device;
a memory configured to store a data information for operation; and
a power module configured to generate power,
wherein the display device comprises:
a substrate;
a display element layer disposed on the substrate, and comprising a first electrode, a light emitting layer, and a second electrode;
a phase retardation layer disposed on the display element layer;
a barrier layer disposed on a side surface of the phase retardation layer; and
a wire grid polarizer disposed on the phase retardation layer,
wherein the barrier layer contains a moisture absorbent material.
